(19) United States
(12) Patent Application Publication
(10) Pub. No.: US 2010/0156549 A1
(43) Pub. Date: Jun. 24, 2010

(54) VOLTAGE CONTROLLED OSCILLATOR

(76) Inventors: Shinichiro Uemura, Osaka (JP); Atsushi Ohara, Shiga (JP); Masatake Irie, Kyoto (JP)

Correspondence Address: MCDERMOTT WILL & EMERY LLP, 600 13TH STREET, NW, WASHINGTON, DC, 20005-3096, US

(21) Appl. No.: 12/551,902

(22) Filed: Sep. 1, 2009

(30) Foreign Application Priority Data
Dec. 22, 2008 (JP) 2008-325242

(51) Int. Cl. H03B 5/08

(52) U.S. Cl. 331/167

(57) ABSTRACT

A voltage controlled oscillator includes a loop-shaped transmission line, an active circuit connected to a signal line, and a variable capacitor block connected to the signal line and having a plurality of variable capacitor units. Each variable capacitor unit includes a variable capacitor element, a control terminal for applying a control voltage to the variable capacitor element, and a reference voltage terminal for applying a reference voltage to the variable capacitor element. At least two variable capacitor units receive different reference voltages.

### CROSS-REFERENCE TO RELATED APPLICATION

This application claims priority to Japanese Patent Application No. 2008-325242 filed on Dec. 22, 2008, the disclosure of which including the specification, the drawings, and the claims is hereby incorporated by reference in its entirety.

### BACKGROUND

The present disclosure relates to a voltage controlled oscillator and specifically to a voltage controlled oscillator used for a semiconductor integrated circuit.

Wireless radios as represented by mobile phones have receivers and transmitters. The receiver includes a down converter and a frequency synthesizer to convert a received signal into a baseband signal having a low frequency. The transmitter includes an up converter and the frequency synthesizer to convert the baseband signal into a transmitting signal having a high frequency. The frequency synthesizer has a voltage controlled oscillator or a digital control oscillator (a type of the voltage controlled oscillator). Recently, efforts are being made to achieve higher performance, lower power consumption, and down-sizing of wireless radios. Similarly, lower phase noise, lower power consumption, and down-sizing of frequency synthesizers, which are used in the wireless radios, are demanded, too. Performance of frequency synthesizers is mainly dependent on performance of voltage controlled oscillators or digital control oscillators, and therefore, lower phase noise, lower power consumption, and down-sizing of the voltage controlled oscillators or digital control oscillators are crucial. Various circuit types are used for the voltage controlled oscillators, such as a ring oscillator type, an LC resonance type which uses inductors and capacitors, and a standing-wave oscillator (SWO) type. In recent years, rotary traveling-wave (RTW) type oscillators are receiving attention among others. The RTW type oscillator has a transmission line like a Moebius strip which is twisted so as to form two circles, and oscillation is caused by an active circuit interposed between two signal lines which constitute the transmission line (see, for example, U.S. Pat. No. 6,556,089). The RTW type oscillator can be implemented compactly on a semiconductor substrate, and is thus expected to greatly contribute to the down-sizing of the frequency synthesizers.

### SUMMARY

However, conventional voltage controlled oscillators have the following problems. In the case where a frequency synthesizer is configured using a voltage controlled oscillator, the transient response and noise band characteristics of the frequency synthesizer are dependent on a frequency sensitivity to a control voltage. Thus, in the case where the frequency does not change linearly according to the change of the voltage, the characteristics of the frequency synthesizer are varied according to the frequency. Moreover, in the area where the frequency sensitivity to the control voltage is high, the frequency is varied by a small noise received at a frequency control terminal, and thus, a phase noise characteristic is degraded.

To implement the voltage controlled oscillator on a semiconductor substrate, a MOS varactor (a metal oxide semiconductor (MOS) transistor) is used as a variable capacitor element. The MOS varactor has a characteristic that its capacitance value significantly changes in the area where a voltage is close to a threshold voltage of the MOS varactor. As such, the oscillation frequency of the voltage controlled oscillator using the MOS varactor significantly changes in the area where the voltage is close to the threshold voltage of the MOS varactor.

Using a variable capacitor element having high linearity may improve the noise characteristic. However, using a variable capacitor element having high linearity so as to achieve the voltage controlled oscillator on the semiconductor substrate requires a large cost, and thus, is difficult.

The present invention is advantageous in solving the above problems and achieving an RTW type voltage controlled oscillator with a superior phase noise characteristic while using a widely-used variable capacitor element without additional fabrication costs.

To achieve the above, an example voltage controlled oscillator has a structure in which different reference voltages are applied to variable capacitor elements.

Specifically, an example voltage controlled oscillator includes: a loop-shaped transmission line having an odd number of parallel portions in each of which signal lines are arranged in parallel to each other with a space therebetween, and an odd number of intersection portions in each of which the signal lines intersect spatially; active circuits connected to the signal lines; and variable capacitor blocks connected to the signal lines and including a plurality of variable capacitor units, wherein each of the plurality of variable capacitor units includes a variable capacitor element, a control terminal for applying a control voltage to the variable capacitor element, and a reference voltage terminal for applying a reference voltage to the variable capacitor element, and wherein at least two of the plurality of variable capacitor units receive the reference voltages having different values.

In the example voltage controlled oscillator, at least two variable capacitor units receive reference voltages having different values. Thus, values of the control voltage at which the capacitance values of the variable capacitor units are greatly varied cannot be the same between all of the variable capacitor units. Therefore, the rate of change in the total capacitance of the variable capacitor blocks with respect to the control voltage can be lowered, and the frequency sensitivity to the control voltage can thus be lowered. As a result, an RTW type voltage controlled oscillator with a superior phase noise characteristic can be achieved even if a widely-used MOS varactor is used.

### BRIEF DESCRIPTION OF THE DRAWINGS

FIG. 1 is a block diagram showing an example voltage controlled oscillator.

FIG. 2 is a circuit diagram showing a variable capacitor block of an example voltage controlled oscillator.

FIG. 3 is a circuit diagram showing a reference voltage generation circuit of an example voltage controlled oscillator.

FIG. 4 is a graph schematically showing the relationship between a control voltage and a capacitance when a reference voltage is constant.

FIG. 5 is a graph schematically showing the relationship between a control voltage and a capacitance when different reference voltages are applied to respective variable capacitor units.

FIG. 6 is a graph schematically showing the relationship between a control voltage and a capacitance of an example voltage controlled oscillator.

FIG. 7 is a graph schematically showing the relationship between a control voltage and an oscillation frequency of an example voltage controlled oscillator.

FIG. 8 is a graph schematically showing the relationship between a control voltage and a frequency sensitivity of an example voltage controlled oscillator.

FIG. 9 is a diagram of an active circuit of an example voltage controlled oscillator.

FIG. 10 is a block diagram showing an operating current variable circuit of an example voltage controlled oscillator.

FIG. 11 is a circuit diagram showing a concrete example of an operating current variable circuit of an example voltage controlled oscillator.

FIG. 12 is a block diagram showing an example voltage controlled oscillator having a selection circuit.

FIG. 13 is a block diagram showing a fixed capacitor block of an example voltage controlled oscillator.

FIG. 14 is a graph schematically showing the relationship between a control voltage and a capacitance when an example voltage controlled oscillator has a fixed capacitor block.

FIG. 15 is a graph schematically showing the relationship between a control voltage and an oscillation frequency when an example voltage controlled oscillator has a fixed capacitor block.

FIG. 16 is a block diagram showing an example voltage controlled oscillator having a reference voltage variable circuit.

FIG. 17 is a graph schematically showing the relationship between a control voltage and a capacitance when an example voltage controlled oscillator has a reference voltage variable circuit.

FIG. 18 is a block diagram showing an example voltage controlled oscillator having a control voltage fixing circuit.

FIG. 19 is a graph schematically showing the relationship between a control voltage and a capacitance when an example voltage controlled oscillator has a control voltage fixing circuit.

### DETAILED DESCRIPTION

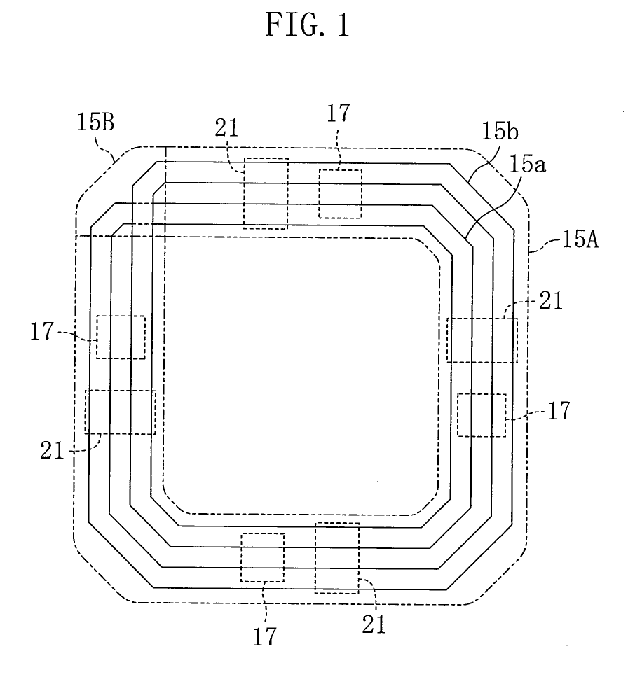

FIG. 1 shows a structure of a voltage controlled oscillator according to one embodiment. As shown in FIG. 1, the voltage controlled oscillator of the present embodiment is an RTW type voltage controlled oscillator. Specifically, the voltage controlled oscillator of the present embodiment includes a loop-shaped transmission line 15, and active circuits 17 and variable capacitor blocks 21. The loop-shaped transmission line 15 has a parallel portion 15A in which a first signal line 15a and a second signal line 15b are arranged in parallel to each other, with a space therebetween, and an intersection portion 15B in which the first signal line 15a and the second signal line 15b intersect spatially. At the intersection portion 15B, the first signal line 15a and the second signal line 15b are isolated from each other. However, since the transmission line 15 includes the one parallel portion 15S and the one intersection portion 15B, the first signal line 15a and the second signal line 15b are electrically coupled to each other, thereby forming a single loop-shaped transmission line 15. The number of the parallel portions 15A and the intersection portions 15B are not limited to one, but may be any odd numbers.

The transmission line can be considered as a circuit in which a plurality of inductances and capacitances are connected. In this case, a phase rotational speed Vp can be represented by

$${v}_{p} = \frac{1}{\sqrt{{L}_{0} {C}_{0}}} \qquad ( 1 )$$

wherein L₀ represents an inductance per unit length and C₀ represents a capacitance per unit length. One round of the transmission line 15 corresponds to one circle of the phase. Thus, the oscillation frequency f₀ of the transmission line 15 can be represented by

$${f}_{0} = \frac{{v}_{p}}{2 λ} = \frac{1}{2 \sqrt{{L}_{0} {C}_{0} \cdot {λ}^{2}}} = \frac{1}{2 \sqrt{{L}_{1} {C}_{1}}} \qquad ( 2 )$$

wherein λ represents a wavelength; L₁ represents the sum of inductances corresponding to half a round of the transmission line 15; and C1 represents the sum of capacitances to the ground which correspond to half a round of the transmission line 15. In the case where capacitor elements are deliberately added, C₁ represents the sum of the capacitance of the added capacitor elements and parasitic capacitances. In the case of the circuit of FIG. 1, C₁ is the total sum of the capacitance value of the variable capacitor blocks 21, capacitance components of the active circuits 17 (excluding the variable capacitor blocks 21), and a capacitance component of the transmission line itself. Thus, the oscillation frequency of the voltage controlled oscillator is varied by applying a control voltage to the variable capacitor blocks 21 and thereby changing the capacitance value of the variable capacitor blocks 21. At this time, if change in the capacitance value of the variable capacitor blocks 21 is significant, the frequency sensitivity to the control voltage is increased. As a result, the phase noise characteristic of the voltage controlled oscillator is degraded.

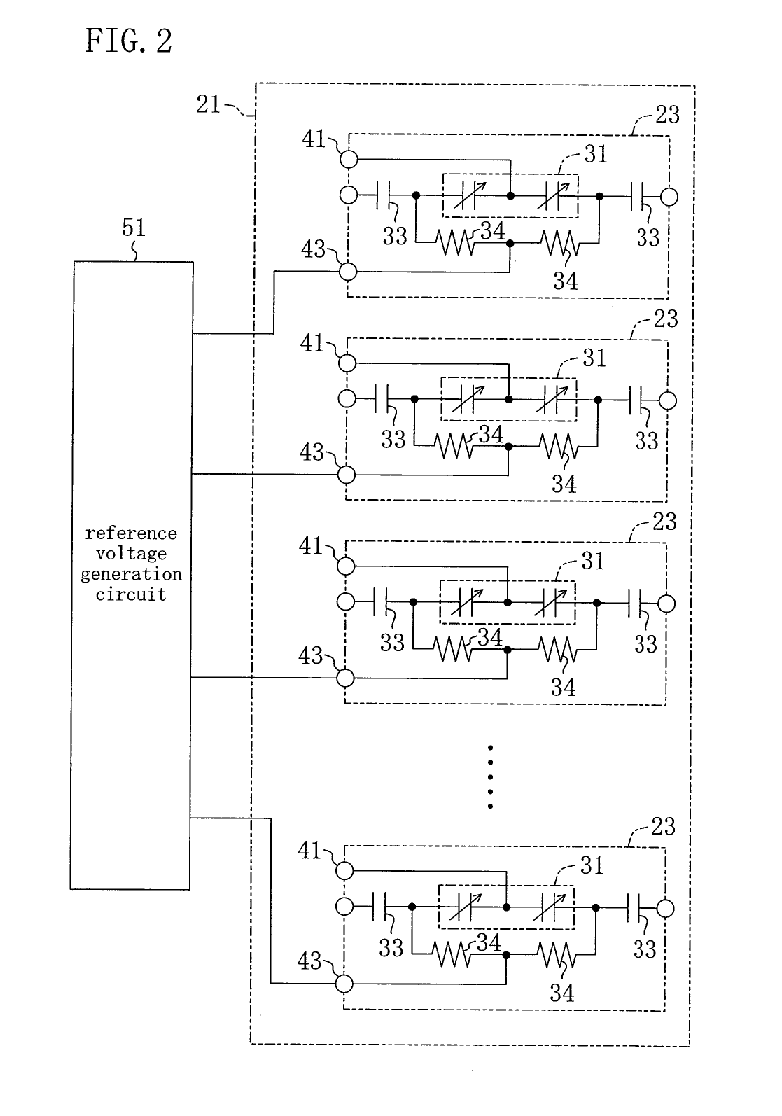

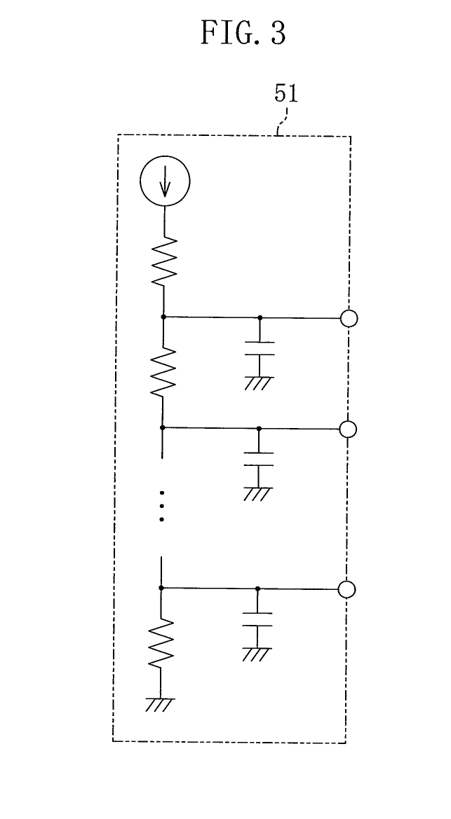

FIG. 2 shows an example circuit configuration of the variable capacitor block 21. The variable capacitor block 21 includes a plurality of variable capacitor units 23. Each variable capacitor unit 23 includes a MOS type varactor element 31 which has a gate terminal and first and second terminals. The gate terminal of the varactor element 31 is connected to a control terminal 41 used to apply a control voltage for controlling a frequency. The first and second terminals are connected to the first signal line 15a or the second signal line 15b shown in FIG. 1, each through a direct current component blocking capacitor 33 for blocking a direct current component. The node for coupling the first terminal to its corresponding direct current component blocking capacitor 33 and the node for coupling the second terminal to its corresponding direct current component blocking capacitor 33 are connected to a reference voltage terminal 43 for applying a reference voltage, each through a high frequency blocking resistor 34. The reference voltage terminal 43 is coupled to a reference voltage generation circuit 51. The reference voltage generation circuit 51 generates a plurality of reference voltages having different voltages. Configuration of the reference voltage generation circuit 51 is not particularly limited, and may be easily configured by using a current source or a voltage source and a voltage dividing resistor, as shown in FIG. 3, for example.

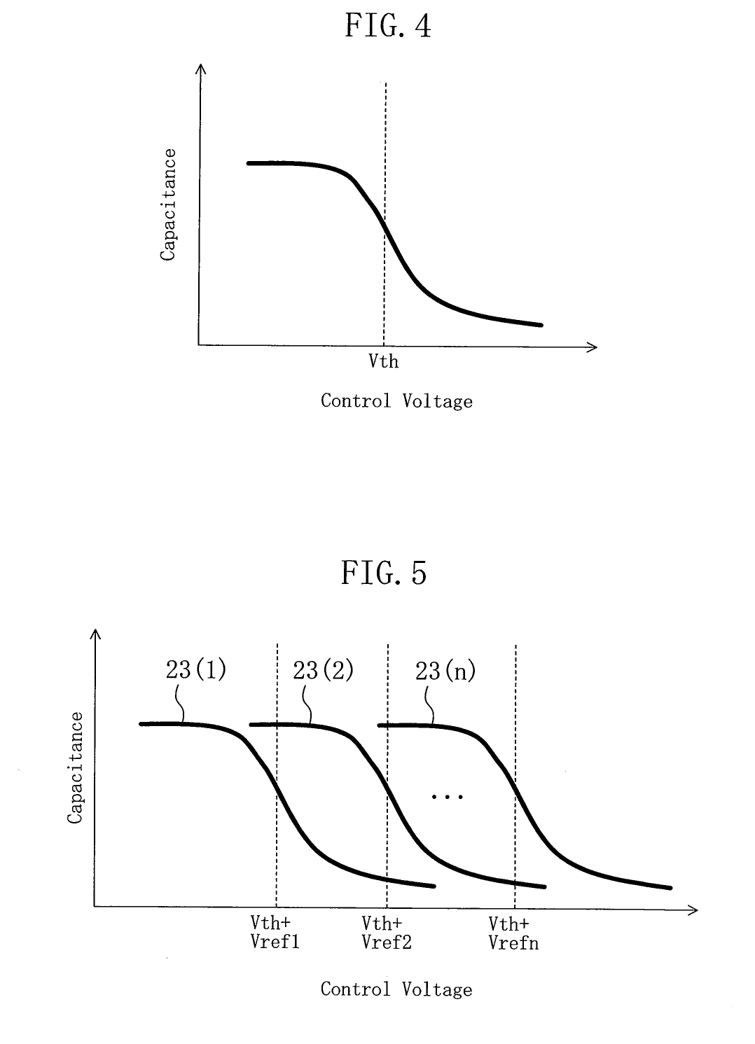

Now, if the reference voltage applied to each variable capacitor unit 23 is a ground voltage (0 V) and constant, the relationship between the capacitance value of each variable capacitor unit 23 and the control voltage applied to the control terminal 41 is as shown in FIG. 4. In this case, the capacitance value of each variable capacitor unit 23 widely varies in the area where the control voltage is close to a threshold voltage Vₜₕ of the varactor element 31. Thus, the frequency sensitivity to the control voltage is increased in the area where the control voltage is close to the threshold voltage Vₜₕ. As a result, the phase noise characteristic of the voltage controlled oscillator is degraded.

On the other hand, if different reference voltages are applied to the variable capacitor units 23, the relationship between the capacitance value of each variable capacitor unit 23 and the control voltage is as shown in FIG. 5. The capacitance value of the variable capacitor unit 23 (1) to which a reference voltage V_{ref1} is applied, is greatly varied in the area where the control voltage is close to a voltage which is higher than the threshold voltage Vₜₕ by V_{ref1}. The capacitance value of the variable capacitor unit 23 (2) to which a reference voltage V_{ref2} is applied, is greatly varied in the area where the control voltage is close to a voltage which is higher than the threshold voltage Vₜₕ by V_{ref2}. The capacitance value of the n^{th} variable capacitor unit 23 (n) to which a reference voltage V_{refn} is applied, is greatly varied in the area where the control voltage is close to a voltage which is higher than the threshold voltage Vₜₕ by V_{refn}.

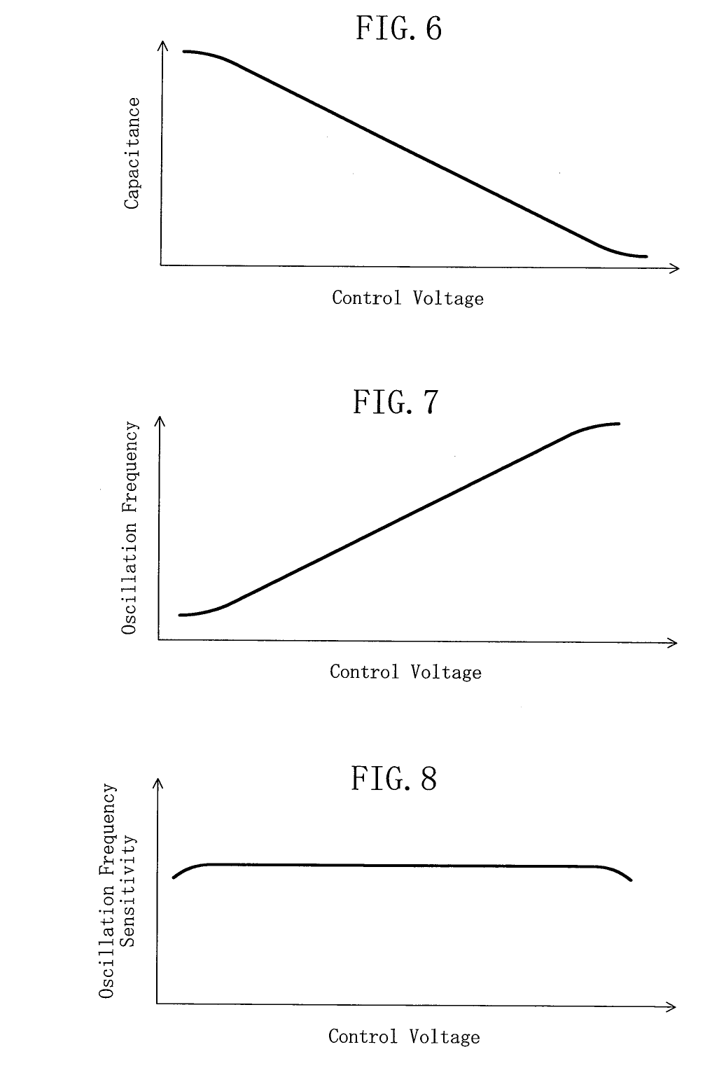

By adjusting the value of the reference voltage applied to each variable capacitor unit 23, the total capacitance of the variable capacitor blocks 21 can be reduced gradually, and can be almost linear with respect to the control voltage as shown in FIG. 6. This enables the frequency to be gradually varied with respect to the control voltage as shown in FIG. 7, and the frequency sensitivity to the control voltage can be almost constant as shown in FIG. 8. As a result, a frequency sensitivity to the control voltage can be maintained low in a wide range of control voltage values, and therefore, the phase noise characteristic of the voltage controlled oscillator is not degraded.

An example in which the frequency sensitivity is maintained almost constant by applying different reference voltages to the variable capacitor units 23 is described. However, the frequency sensitivity does not necessarily have to be almost constant. In some cases, a frequency sensitivity that can achieve a predetermined phase noise characteristic may be enough. In such cases, for example, changing the reference voltage applied to one variable capacitor unit 23 to a value that is different from the reference voltages applied to the other variable capacitor units 23 may be enough.

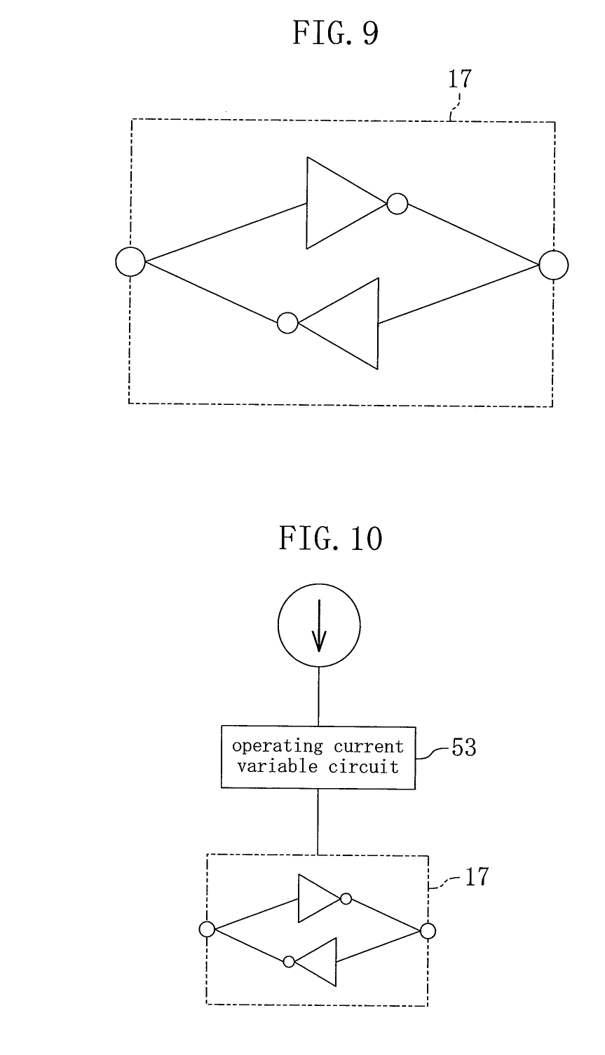

FIG. 9 shows an example active circuit 17 used in a voltage controlled oscillator of the present embodiment. The active circuit 17 may be configured to have the structure in which two inverters are connected in parallel and are directed in opposite directions. Due to this structure, energies for maintaining the amplitudes of two inverted, amplified signals constant can be supplied to the two parallel signal lines. As a result, stable oscillation is possible.

The larger the operating current supplied to the active circuit 17 is, the higher the voltage amplitude of the voltage controlled oscillator becomes. Thus, to improve the phase noise characteristic of the voltage controlled oscillator, it is preferable that the operating current supplied to the active circuit 17 is large. However, if a large operating current is supplied to the active circuit 17, it increases the power consumption of the voltage controlled oscillator. On the other hand, according to the voltage controlled oscillator of the present embodiment, the frequency sensitivity to the control voltage can be kept low, and therefore, the phase noise characteristic is not degraded. Thus, in the case where the voltage controlled oscillator exhibits a sufficient phase noise characteristic, the operating current supplied to the active circuit 17 can be reduced.

By using an operating current variable circuit 53 for varying the operating current supplied to the active circuit 17 as shown in FIG. 10, the operating current is reduced, thereby reducing power consumption, in the case where a sufficient phase noise characteristic can be ensured due to, for example, a low frequency. On the other hand, in the case where a superior phase noise characteristic is required due to a high frequency, the operating current supplied to the active circuit 17 is increased. The amount of the operating current can be changed according to a communication mode, as well. For example, different phase noise characteristics are required between the global system for mobile communication (GSM) mode and universal mobile telecommunication system (UMTS) mode for mobile phones. Changing the operating current supplied to the active circuit 17 enables the fulfillment of both the required phase noise characteristics and prevention of an excess amount of current.

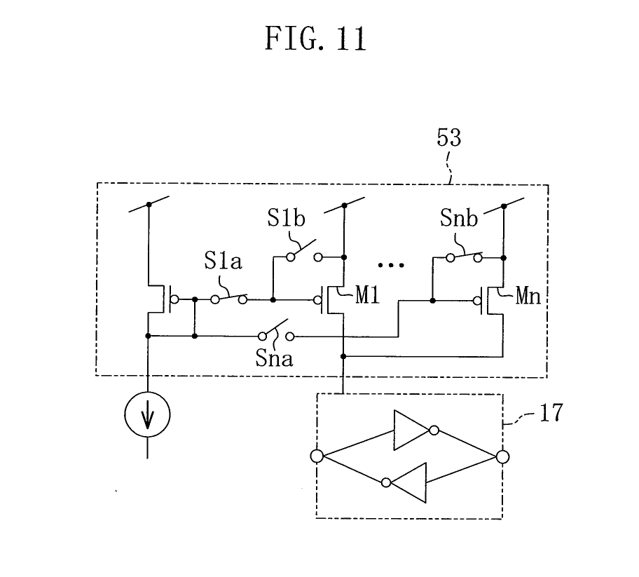

The operating current variable circuit 53 may be structured as shown, for example, in FIG. 11, in which a gate of a current mirror circuit has a switch for controlling the operating current supplied to the active circuit 17. In FIG. 11, operation of a switch S1a and operation of a switch S1b are linked to each other. When the S1a is on, S1b is off. This operation turns the transistor M1 on, and the operating current is supplied to the active circuit 17 from the first current mirror circuit. On the other hand, when the S1a is off, the S1b is on. This operation turns the transistor M1 off, and no operating current is supplied to the active circuit 17 from the first current mirror circuit. In FIG. 11, n current mirror circuits are connected in parallel, and each current mirror circuit can be controlled in like manner. Values of the operating current supplied to the active circuit 17 can thus be varied.

In the case where a plurality of active circuits 17 are provided, the operating current for a specific active circuit 17 may be controlled, or the operating currents for all the active circuits 17 may be controlled. In the case where the operating currents for the plurality of active currents 17 are controlled, the operating currents may be controlled separately for each active current 17, or may be controlled simultaneously for the plurality of active circuits 17.

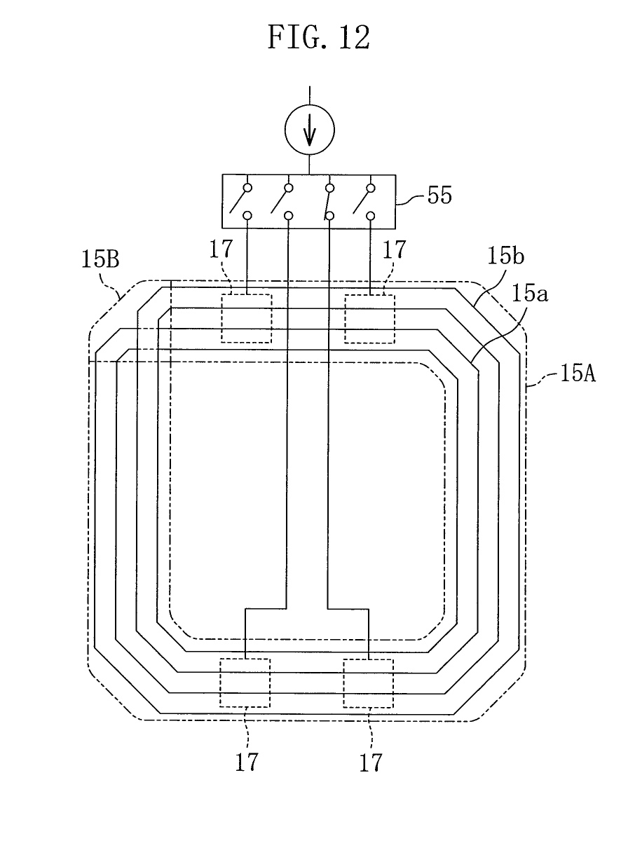

As shown in FIG. 12, in the case where a plurality of active circuits 17 are provided, a selection circuit 55 which supplies the operating current only to a predetermined active circuit 17 may be provided. The selection circuit 55 may be configured by a current mirror circuit which has a switching element at a gate, such as shown in FIG. 11. In this case, the number of the active circuits 17 to be operated may be reduced if a sufficient phase noise characteristic is ensured. The number of the active circuits 17 to be operated may be increased if a superior phase noise characteristic is required.

There are cases in which the active circuits 17 have slightly different characteristics if provided at a plurality of locations on a substrate. In such cases, using only an active circuit 17 which has a superior characteristic is possible. For example, the output of the voltage controlled oscillator may be monitored and an active circuit 17 used when the voltage controlled oscillator exhibits the highest amplitude may be selected. Parameters other than the amplitude can be used, too. Monitoring may be done beforehand in the inspection step to select an active circuit 17 to be operated, or monitoring may be done as appropriate during the operation of the voltage controlled oscillator to switch between active circuits 17 to be operated.

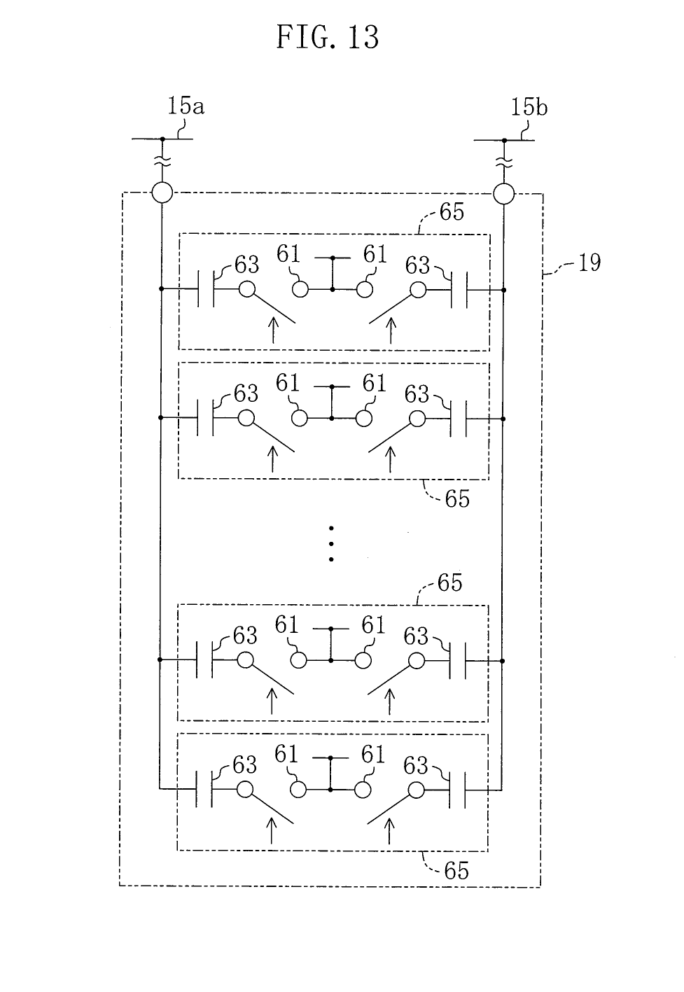

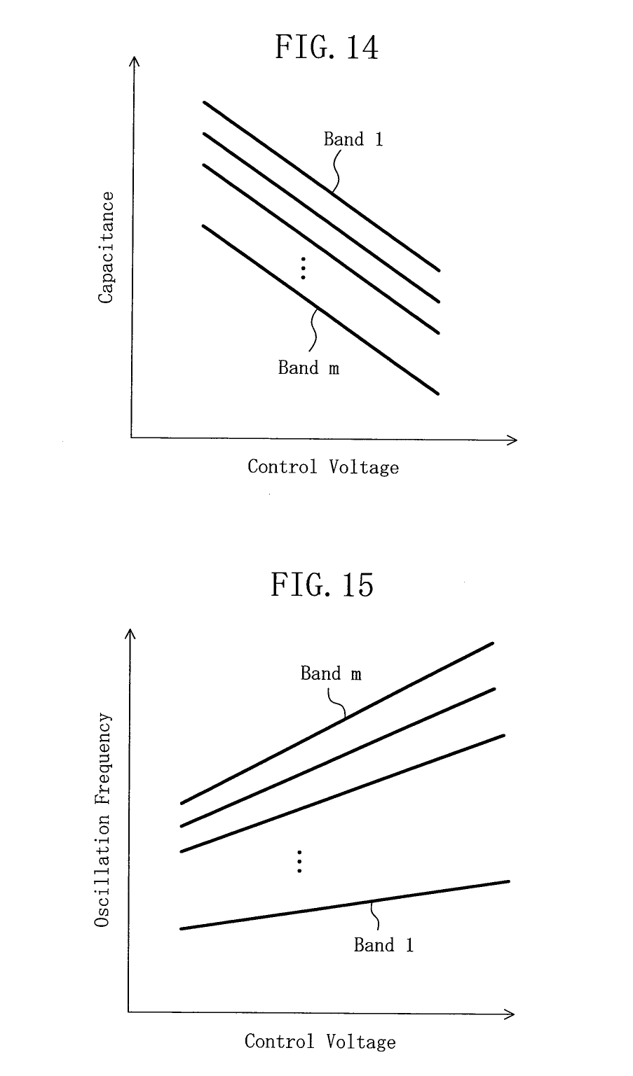

To increase a range of the oscillation frequency of the voltage controlled oscillator, a fixed capacitor block 19 as shown in FIG. 13 may be provided. The fixed capacitor block 19 includes a plurality of fixed capacitor units 65. The fixed capacitor units 65 are provided between the first signal line 15a and the second signal line 15b. Each fixed capacitor unit 65 includes fixed capacitor elements 63. The fixed capacitor elements 63 can be freely connected to or disconnected from the first signal line 15a and the second signal line 15b, each by a switching element 61. It is thus possible to arbitrarily select a fixed capacitor element 63 which couples between the first signal line 15a and the second signal line 15b. According to this structure, the relationship between the control voltage and the total capacitance value of the variable capacitor block 21 and the fixed capacitor block 19 is as shown in FIG. 14, which exhibits a plurality of frequency characteristics (bands). By switching the bands using the fixed capacitor block 19, the change in the total capacitance can be increased while maintaining the change in the capacitance of the variable capacitor block 21 small with respect to the control voltage. Hence, the range of the oscillation frequency of the voltage controlled oscillator can be increased while maintaining the frequency sensitivity to the control voltage low, thereby making it possible to improve the phase noise characteristic of the voltage controlled oscillator.

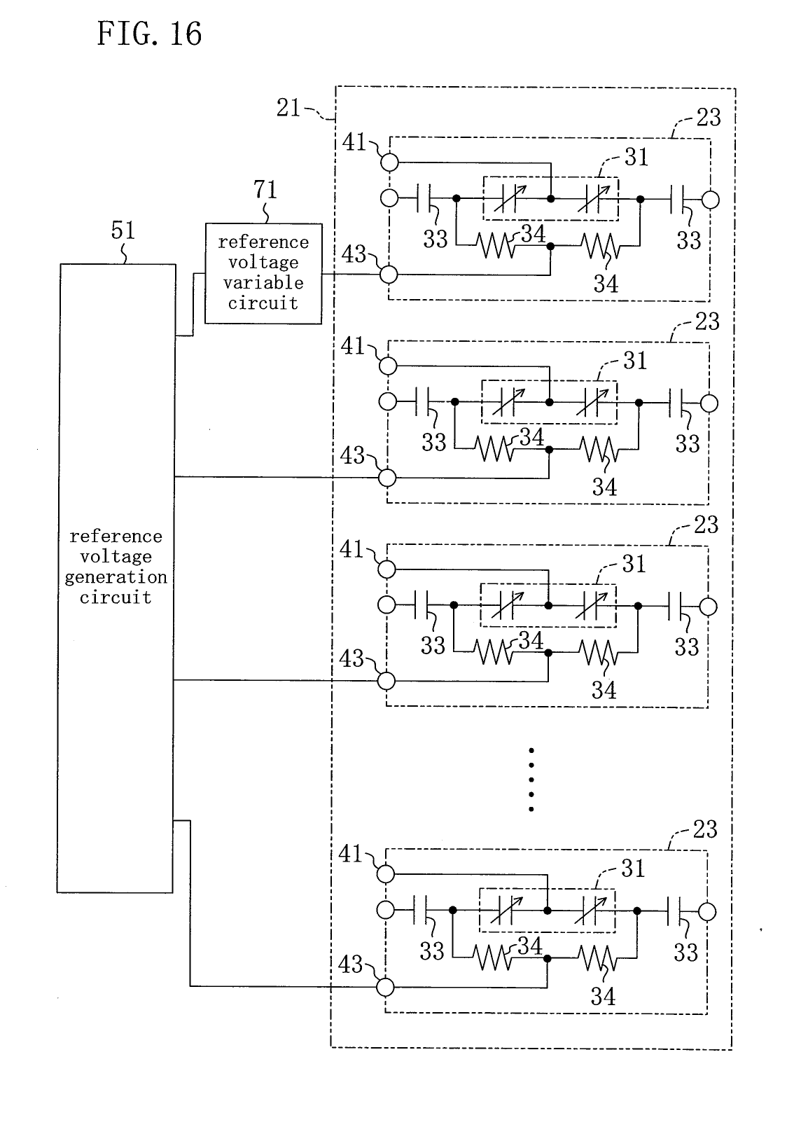

The oscillation frequency and the capacitance value of the voltage controlled oscillator have the relationship such as defined by the equation (2). According to the equation, an attempt to cover a very wide range of the oscillation frequency while maintaining a linear change in the capacitance, results in a significant increase in frequency sensitivity to the control voltage, and hence degradation of the phase noise characteristic, in the area where the oscillation frequency is high as shown in FIG. 15. On the contrary, in the area where the oscillation frequency is low, there may be a problem that the oscillation frequency does not change much due to a very low frequency sensitivity to the control voltage. Providing a reference voltage variable circuit 71 for varying a value of the reference voltage applied to the variable capacitor unit 23, as shown in FIG. 16, is effective in solving such the problem as in the above.

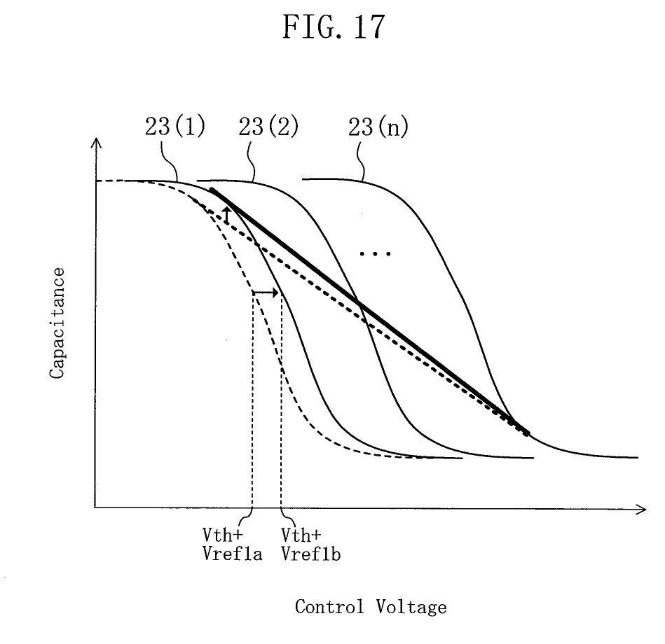

Values of the reference voltage supplied to a predetermined variable capacitor unit 23 can be changed by the reference voltage variable circuit 71. For example, in the case where the reference voltage variable circuit 71 is connected to a first variable capacitor unit 23 (1) to allow the reference voltage applied to the first variable capacitor unit 23 (1) to be varied between V_{ref1a} and V_{ref1b}, the relationship between the control voltage and the capacitance value of the variable capacitor blocks 21 is as shown in FIG. 17. If the reference voltage supplied to the first variable capacitor unit 23 (1) is varied from V_{ref1a} to V_{ref1b}, the voltage at which the capacitance of the first variable capacitor unit 23 (1) greatly varies is increased from Vₜₕ+V_{ref1a} to Vₜₕ+V_{ref1b}. Thus, the rate of change in the total capacitance value of the variable capacitor blocks 21 with respect to the control voltage is increased. The frequency sensitivity to the control voltage can be maintained almost constant, if the change in the capacitance value is increased by varying the reference voltage in the area where, due to a low oscillation frequency, the frequency sensitivity to the control voltage is low, and if the change in the capacitance value is reduced in the area where, due to a high oscillation frequency, the frequency sensitivity to the control voltage is high. In this case, control of the reference voltage variable circuit 71 and control of switching bands in the fixed capacitor block 19 may be linked to each other.

The variable capacitor unit 23 to which the reference voltage variable circuit 71 is connected may be determined according to the amount of change in required capacitance values. The reference voltage variable circuit 71 may be connected to one variable capacitor unit 23, and may also be connected to each of a plurality of variable capacitor units 23. An example in which the reference voltage is varied according to the oscillation frequency is described in the above, but the reference voltage can be varied according to a communication mode, too.

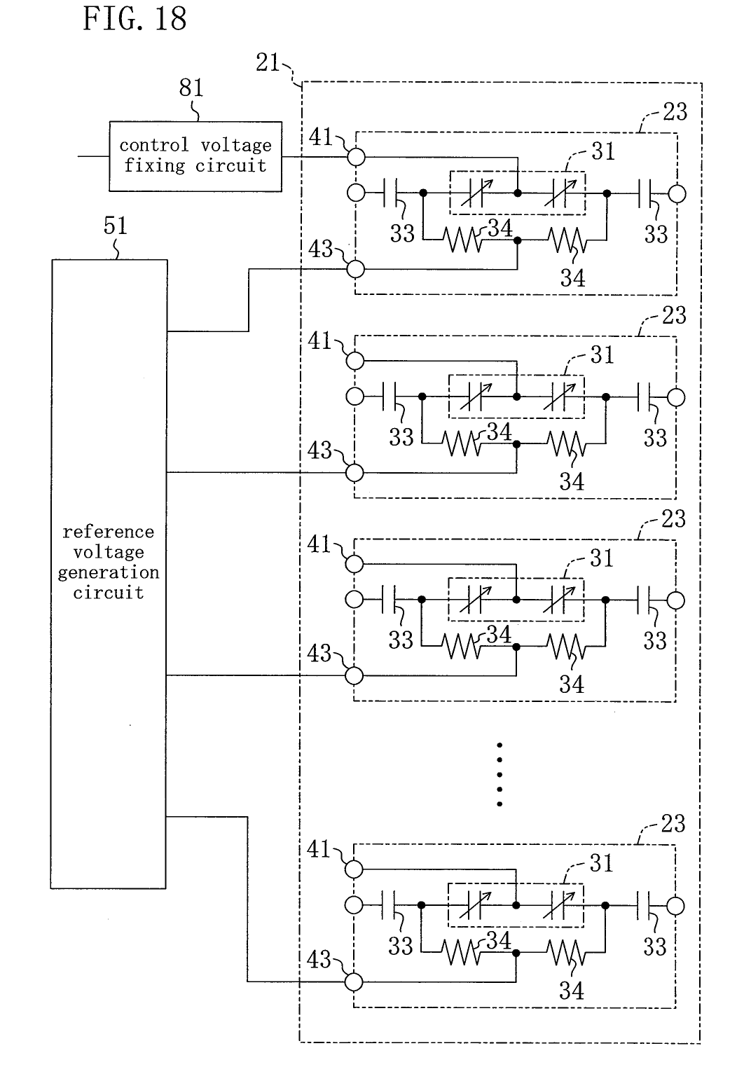

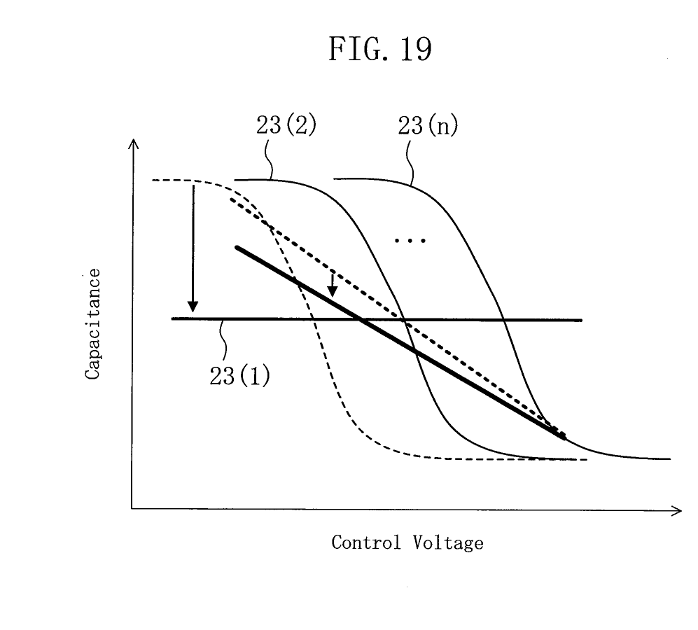

To vary the rate of change in the total capacitance value of the variable capacitor blocks 21 with respect to the control voltage, a control voltage fixing circuit 81 may be provided, as shown in FIG. 18, for fixing a control voltage supplied to the variable capacitor unit 23 to a predetermined voltage. The control voltage fixing circuit 81 may be, for example, a switching circuit which connects a control terminal and a power source having a predetermined voltage. For example, in the case where the control voltage fixing circuit 81 is connected to a first variable capacitor unit 23 (1) to allow the control voltage applied to the first variable capacitor unit 23 (1) to be fixed to a constant voltage around Vₜₕ, the relationship between the control voltage and the capacitance value of the variable capacitor blocks 21 is as shown in FIG. 19.

If the voltage applied to the control terminal of the first variable capacitor unit 23 (1) is held constant, the capacitance value of the first variable capacitor unit 23 (1) stays constant irrespective of the control voltage. Thus, the rate of change in the total capacitance value of the variable capacitor blocks 21 with respect to the control voltage becomes lower compared to when the control voltage is applied to the first variable capacitor unit 23 (1). Accordingly, the rate of change in the capacitance value with respect to the control voltage can be within an appropriate range according to the oscillation frequency, a communication mode, etc.

The variable capacitor unit 23 to which the control voltage fixing circuit 81 is connected may be determined according to the amount of change in required capacitance values. The control voltage fixing circuit 81 may be connected to one variable capacitor unit 23, and also may be connected to each of a plurality of variable capacitor units 23. Further, control of the control voltage fixing circuit 81 and control of switching bands in the fixed capacitor block 19 may be linked to each other. Moreover, providing both of the control voltage fixing circuit 81 and the reference voltage variable circuit 71 is possible.

FIG. 1 shows an example in which the variable capacitor blocks 21 are located at a plurality of different places on the transmission line 15. However, the variable capacitor blocks 21 may be located at the same place. In the case where the variable capacitor block 21 are located at a plurality of different places, each variable capacitor block 21 may include the same number of variable capacitor units 23. In this case, the same reference voltage can be applied to the variable capacitor units 23 which are included in different variable capacitor blocks 21 and which correspond to one another. The same reference voltage can be applied to the variable capacitor units 23 included in the variable capacitor blocks 21 located at the same place, and different reference voltages can be applied to the variable capacitor units 23 included in the variable capacitor blocks 21 located at different places.

The fixed capacitor block 19 may be configured by a plurality of parts which are located at a plurality of different places, or may be located collectively at one place. The capacitance values of all the fixed capacitor units 65 included in a fixed capacitor block 19 may be equal to each other, or a fixed capacitor block 19 may include multiple types of fixed capacitor units 65 whose capacitance values are different from one another. The number of the fixed capacitor units 65 included in a fixed capacitor block 19 may be determined based on the number of bands needed. It is preferable that the capacitance value of each fixed capacitance unit 65 is set such that ranges of variable capacitance values overlap with nearby bands.

At least one active circuit 17 is enough, but if a plurality of active circuits 17 are provided, the active circuits 17 may be located at a plurality of different places, or may be collectively located at the same place.

An example in which the transmission line 15 includes one parallel portion 15A and one intersection portion 15B is shown in FIG. 1. However, the number is not limited to one as long as the transmission line 15 includes an odd number of parallel portions 15A and an odd number of intersection portions 15B. An example in which the transmission line 15 has an approximately square shape in plan view is described. However, the transmission line 15 may have a different shape, such as a circle, a regular hexagon, and a star having points, etc., in plan view.

As described in the above, an example voltage controlled oscillator can realize an RTW type voltage controlled oscillator with a superior phase noise characteristic while utilizing a widely-used variable capacitor element without additional costs, and is particularly useful as a voltage controlled oscillator or the like used in a semiconductor integrated circuit.

The description of one embodiment of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A voltage controlled oscillator comprising:
a loop-shaped transmission line having an odd number of parallel portions in each of which signal lines are arranged in parallel to each other with a space therebetween, and an odd number of intersection portions in each of which the signal lines intersect spatially,
active circuits connected to the signal lines, and
variable capacitor blocks connected to the signal lines and including a plurality of variable capacitor units, wherein
each of the plurality of variable capacitor units includes a variable capacitor element, a control terminal for applying a control voltage to the variable capacitor element, and a reference voltage terminal for applying a reference voltage to the variable capacitor element, and
at least two of the plurality of variable capacitor units receive the reference voltages having different values.

2. The voltage controlled oscillator of claim 1, wherein
the variable capacitor element is a varactor element having a gate terminal, a first terminal and a second terminal,
each of the plurality of variable capacitor units includes two capacitors connected to the first terminal and the second terminal, respectively,
the gate terminal is connected to the control terminal, and
a node for coupling the first terminal to one capacitor and a node for coupling the second terminal to the other capacitor are connected to the reference voltage terminal.

3. The voltage controlled oscillator of claim 1, further comprising an operating current variable circuit capable of varying an operating current supplied to the active circuits.

4. The voltage controlled oscillator of claim 3, wherein
multiple ones of the active circuit are provided, and
the operating currents supplied to the plurality of active circuits are controlled by the operating current variable circuit independently from one another.

5. The voltage controlled oscillator of claim 1, wherein
the voltage controlled oscillator further comprises a selection circuit for selecting and operating at least one of the plurality of active circuits.

6. The voltage controlled oscillator of claim 1, further comprising a fixed capacitor block connected to the signal lines and including a fixed capacitor unit, wherein
the fixed capacitor unit includes a fixed capacitor element and a switching element for turning the fixed capacitor element on or off.

7. The voltage controlled oscillator of claim 1, further comprising a reference voltage variable circuit capable of varying a value of the reference voltage applied to at least one of the plurality of variable capacitor units.

8. The voltage controlled oscillator of claim 1, further comprising a control voltage fixing circuit for fixing the control voltage applied to part of the plurality of variable capacitor units to a predetermined voltage.
